(19) United States
(12) Patent Application Publication
(10) Pub. No.: US 2005/0285494 A1
(43) Pub. Date: Dec. 29, 2005

(54) Color-converting light emitting device including fluorescent powder having large grain diameter, method of producing the same, and resin composition used therein

(75) Inventors: Sung-Bin Cho, Suwon City (KR); Won-Young Chung, Suwon City (KR); Young-Sik Oh, Suwon City (KR); Hyun-Min Kim, Suwon City (KR); Young-Hwan Kim, Yongin City (KR)

Correspondence Address: Richard L. Byrne, 700 Koppers Building, 436 Seventh Avenue, Pittsburgh, PA, 15219-1818, US

(73) Assignee: Lumimicro Corp. Ltd.

(21) Appl. No.: 10/956,567

(22) Filed: Oct. 1, 2004

(30) Foreign Application Priority Data
Jun. 28, 2004 (KR) 10-2004-0049116

(51) Int. Cl. H01L 33/00; C09K 11/02; C09K 11/08; H05B 33/00

(52) U.S. Cl. 313/112; 313/502; 428/690; 428/917; 428/323; 252/301.36; 257/98; 427/66

(57) ABSTRACT

Disclosed is a color-converting light emitting device, which includes a light emitting element for emitting light with a predetermined wavelength and a color-converting member for absorbing a portion of light emitted from the light emitting element to convert the wavelength of the light into another wavelength. The present invention provides the color-converting light emitting device, which includes a gallium nitride-based light emitting diode having an emission spectrum at a visible ray region, and a color-converting member absorbing light from the diode to convert the wavelength of the light into another wavelength. The color-converting member includes a transparent resin and a garnet-based fluorescent powder dispersed in the transparent resin, and the fluorescent powder has a grain size distribution in which a minimum grain diameter is 10 μm or more and a mean grain diameter (d₅₀) is 20 μm or more.

### BACKGROUND OF THE INVENTION

1. Field of the Invention

The present invention pertains, in general, to a semiconductor light emitting element and, more particularly, to a color-converting light emitting device, which includes a light emitting element for emitting light with a predetermined wavelength and a color-converting member for absorbing a portion of light emitted from the light emitting element to convert the wavelength of the light into another wavelength, and a method of producing the same.

2. Description of the Prior Art

A white LED has lately attracted considerable attention as a light source for a flashlight, or a backlight and an illuminator of a liquid crystal display of a portable electronic product, such as a mobile phone, a camcorder, a digital camera, or a PDA.

Various methods of producing the white LED are known. With respect to this, since a technology of producing a gallium nitride-based light emitting diode, which has high brightness and emits light with a blue wavelength, has been developed, many efforts have been made to develop a color-converting light emitting device, which employs a blue light emitting element as a light source, and in which a fluorescent pigment excited and becoming luminescent by light emitted from the blue light emitting element is coated on a path of the light, thereby combining light having a blue color with light emitted from the fluorescent pigment to realize white light.

For example, Korean Pat. Laid-Open Publication No. 2000-0029696 discloses a white light emitting device, which includes an InGaN-based compound semiconductor as a light emitting layer of a light emitting element and employs a garnet-based fluorescent substance activated by Ce.

FIG. 1 illustrates a conventional color-converting light emitting device, particularly a white light emitting device. Referring to FIG. 1, the light emitting device includes an opaque housing 60 made of plastic, a light emitting diode chip 10, which includes an InGaN-based compound semiconductor, positioned in a recess of the housing 60, and a color-converting member 50 situated in the recess to seal the light emitting diode chip 10 and to absorb a portion of light emitted from the light emitting diode chip 10 to convert a wavelength of the light into another wavelength.

A pair of lead frames 20, 30, which is electrically connected to an external power source and connected to the light emitting diode chip 10, is connected to a lower electrode of the light emitting diode chip 10 at a lower side of the light emitting diode chip 10, or connected through a wire 40 to an upper electrode of the light emitting diode chip 10. The light emitting diode chip 10 emits a visible ray with a short wavelength, of which a central wavelength is about 400-530 nm, along a band gap of a light emitting layer when electricity is applied thereto.

The color-converting member 50 contains a matrix phase, which is produced by injecting a resin, such as an epoxy casting resin, or acryl and silicon resins, in a liquid phase thereinto, and hardening the resin, and fluorescent powder 52 dispersed in the matrix phase. A YAG-based fluorescent substance excited and emitting light by a blue shade of light emitted from the light emitting diode chip 10 is frequently used as the fluorescent powder 52, and examples of the YAG fluorescent substance include YAG solid solutions, which is formed by substituting Lu, Sc, La, Gd, or Sm for yttrium, or by substituting Ga, In, or Tb for aluminum. In the case of the above solid solution, a transition of a maximum emission peak occurs according to the degree of substitution of cations. Additionally, two or more kinds of solid solutions with different fluorescent spectra may be used as the fluorescent powder 52 while they are mixed with each other, and the fluorescent powder 52 produced by such a mixture emits fluorescent spectra ranging from green to red. Hence, when the color-converting member 50 is observed from an outside, the fluorescent spectra are mixed with light having the blue color, emitted from the light emitting diode chip 10, thereby realizing a white light emitting device assuring a desired color, that is, white color.

In this regard, an oxide including T, Gd, Ce, La, Al, Sm, and Ga, and a raw material including compounds which are easily oxidized at high temperatures and mixed with each other in a predetermined stoichiometric ratio, or a coprecipitated oxide, which is produced by coprecipitating a solution, obtained by dissolving a rare-earth metal such as Y, Gd, Ce, La, or Sm, in an acid in a predetermined stoichiometric ratio, in an oxalic acid, and a raw material including aluminum oxide and gallium oxide mixed with each other, are sintered at high temperatures to produce a sintered material, and the sintered material is then pulverized to produce the YAG fluorescent substance used as the fluorescent powder. A grain diameter of the pulverized fluorescent substance is known as a main factor in the course of casting the color-converting member. For example, smaller mean grain diameter of the fluorescent substance brings about higher agglutination of the fluorescent substance dispersed in an epoxy resin composition, and larger mean grain diameter of the fluorescent substance brings about lower dispersion stability due to precipitation of the fluorescent substance.

Korean Pat. Laid-Open Publication No. 1999-71493 discloses a color-converting light emitting device, in which garnet-based inorganic fluorescent powder, dispersed in an epoxy casting resin composition, has a grain diameter of 10 μm or less and a mean grain diameter (d₅₀) of 5 μm or less.

According to the above patent, the epoxy casting resin composition contains a single functional and/or multifunctional epoxy casting resin, a reactive diluent, multifunctional alcohol, and a degassing agent. When shapes of particles constituting the fluorescent powder are each a sphere or a plate, the fluorescent powder is neither agglutinated nor precipitated. Thus, it is possible to uniformly disperse the powder and to provide the epoxy resin composition having excellent dispersion stability even though it is stored for a long period.

Meanwhile, Korean Pat. Laid-open Publication No. 2002-79953 discloses a color-converting light emitting diode, which includes a fluorescent material having a small grain diameter and a fluorescent material having a large grain diameter, and in which the fluorescent material having the large grain diameter is distributed in the vicinity of a diode chip in a transparent resin and the fluorescent material having the small grain diameter is distributed outside a color-converting member. In the light emitting diode, the fluorescent material having the large grain diameter of 10-60 μm or more serves to improve light-converting efficiency, and the fluorescent material having the small grain diameter of 0.2-1.5 μm or more functions to diffuse and reflect light to prevent a color stain.

However, in the above patent, the fluorescent material having the large grain diameter is precipitated and aggregates around the LED chip. The densely aggregated fluorescent material having the large grain diameter blocks the passage of wavelength-converted light, resulting in dissipation of light energy. The fluorescent material having a large grain diameter may be sparsely precipitated to avoid the above problem, but it is difficult to practically realize such a sparse precipitation, and the above patent does not provide any concrete solution to the problem.

Furthermore, since the fluorescent material having the small grain diameter, added in conjunction with the fluorescent material having the large grain diameter, is situated between fluorescent particles having the large grain diameter, gaps between the particles are filled up, thereby blocking the wavelength-converted light, resulting in dissipation of light energy.

### SUMMARY OF THE INVENTION

Therefore, the present invention has been made keeping in mind the above problems occurring in the prior art, and an object of the present invention is to provide a color-converting light emitting device, which includes a color-converting member assuring excellent dispersion stability and high brightness even though fluorescent powder having a large grain diameter is employed, and a method of producing the same.

Another object of the present invention is to provide a transparent resin composition used in the color-converting light emitting device.

The above object can be accomplished by providing a color-converting light emitting device, which includes a gallium nitride-based light emitting diode, and a color-converting member absorbing light from the light emitting diode to convert a wavelength of the light into another wavelength. At this time, the color-converting member comprises a transparent resin and a garnet-based fluorescent powder dispersed in the transparent resin, and the fluorescent powder has a grain size distribution in which a minimum grain diameter is 10 μm or more and a mean grain diameter (d₅₀) is 20 μm or more.

Further, the present invention provides a color-converting light emitting device, which includes a gallium nitride-based light emitting diode, and a color-converting member absorbing light from the light emitting diode to convert a wavelength of the light into another wavelength. In this regard, the color-converting member comprises a transparent resin and a garnet-based fluorescent powder dispersed in the transparent resin, and the transparent resin comprises solid and liquid resins at room temperature. Additionally, a content of the solid resin is 50 wt % or more based on a weight of the transparent resin, and the fluorescent powder has a grain size distribution in which a mean grain diameter (d₅₀) is 20 μm or more.

According to a preferred embodiment of the present invention, the solid resin includes triglycidyl isocyanurate (TGIC). Additionally, it is preferable that the mean grain diameter of the fluorescent powder is 50 μm or less.

Furthermore, the present invention provides an epoxy resin casting composition for a color-converting light emitting element, which includes a transparent resin including solid and liquid resins and having a viscosity of 4000-9000 cps, preferably 7000-9000 cps, and an YAG-based fluorescent powder dispersed in the transparent resin and having a mean grain diameter (d₅₀) of 20 μm or more. It is preferable that the mean grain diameter of the fluorescent powder in the composition is 50 μm or less. According to a preferred embodiment of the present invention, the transparent resin includes a solid resin consisting of triglycidyl isocyanurate (TGIC).

As well, the present invention provides a method of producing a color-converting light emitting device, which includes providing a transparent resin including a solid resin, partially hardening the transparent resin, mixing the transparent resin with a garnet-based fluorescent powder to provide a transparent resin composition for the color-converting light emitting device, applying the transparent resin composition onto a gallium nitride-based semiconductor diode chip, and completely hardening the resulting transparent resin composition. At this time, the partial hardening may be conducted by heating at a temperature that is lower than a hardening temperature of the transparent resin. Furthermore, in the above method, the mean grain diameter of the fluorescent powder is 20 μm or more.

### BRIEF DESCRIPTION OF THE DRAWINGS

The above and other objects, features and other advantages of the present invention will be more clearly understood from the following detailed description taken in conjunction with the accompanying drawings, in which:

FIG. 1 illustrates a conventional resin-molded light emitting element; and

FIGS. 2a and 2b are graphs showing brightness as a function of mean grain diameter for each powder, and relative brightness as a function of mean grain diameter for each powder, respectively.

### DETAILED DESCRIPTION OF THE INVENTION

Hereinafter, a detailed description will be given of the present invention.

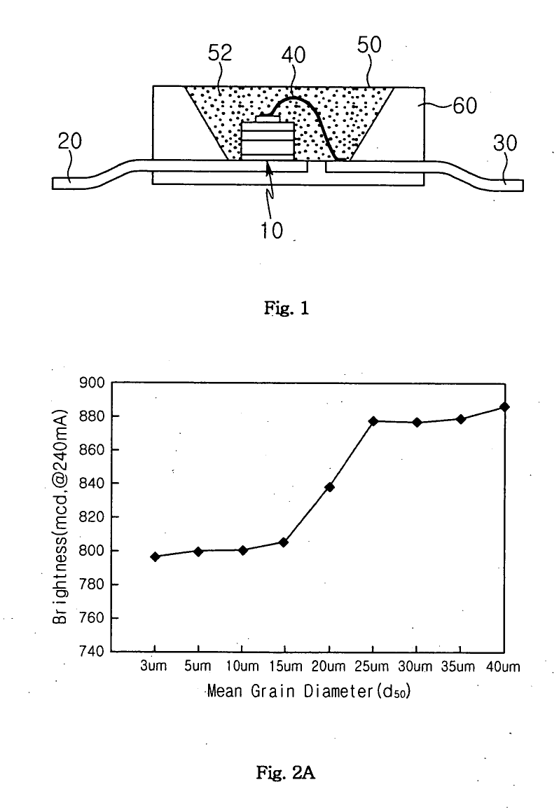

A color-converting light emitting device according to the present invention may have the same structure as a conventional color-converting light emitting device as shown in FIG. 1. However, the color-converting light emitting device according to the present invention is not limited to the structure of FIG. 1, but may be any color-converting light emitting device which includes a light emitting diode chip, and a color-converting member for absorbing at least a portion of light, emitted from the light emitting diode, on a light path of the light emitting diode chip to convert a wavelength of the light into another wavelength.

As described above, the color-converting light emitting device according to the present invention includes a light emitting diode chip and a color-converting member.

In the present invention, the light emitting diode chip includes a light emitting layer made of a gallium nitride-based compound semiconductor. The light emitting diode chip has an emission spectrum characteristic in which the maximum emission peak is shown at 420-460 nm. To accomplish this, the light emitting layer of the light emitting diode chip may consist of AlGaN, InGaN, or InGaAlN compounds. According to a preferred embodiment of the present invention, the light emitting diode chip is an InGaN-based compound semiconductor having the maximum emission peak at 430-450 nm.

The color-converting member is produced by hardening a resin composition, which contains a matrix phase made of a transparent resin and a garnet-based fluorescent substance dispersed in the matrix phase. In the present invention, the transparent resin may be exemplified by an epoxy resin or a silicon resin, and the epoxy resin is preferable. The fluorescent substance in the present invention consists of fluorescent grains having a large grain diameter. At this time, the fluorescent substance having a large grain diameter means fluorescent grains with a mean grain diameter (d₅₀) of 20 μm or more. In the present invention, a grain size distribution of the fluorescent substance having a large grain diameter forms a normal distribution or a pseudo-normal distribution. It should be understood that the term “pseudo-normal distribution” as used in this specification means that a grain size distribution curve does not exactly follow the normal distribution curve, but forms a curve which is similar to the normal distribution curve and exponentially decreases right and left from one central peak point implying the maximum frequency. In this respect, the above term is intended to include a distribution curve while at least one of its both ends being truncated, but to exclude a distribution curve having two or more maximum frequency peaks, such as a bimodal distribution curve.

The fluorescent substance may be a substance which is excited by a light source having a maximum emission peak at 420-460 nm and emits light having a longer wavelength than the light source in a visible ray region.

The fluorescent substance may be exemplified by a substance which has a garnet structure expressed by A₃B₅O₁₂ and is doped by Ce. In this regard, A includes at least one element selected from the group consisting of Y, Lu, Sc, La, Gd, and Sm, and B is at least one element selected from the group consisting of Al, Ga, In, and Tb.

As described above, the color-converting member of the present invention is produced by hardening the resin composition in which garnet-based fluorescent powder is dispersed. The resin composition of the present invention includes a solid resin and a liquid resin at room temperature before it is hardened.

In the case where the resin is an epoxy resin, the liquid resin may be exemplified by typical resins used in the color-converting light emitting device, such as cyclohexene epoxide derivative, bisphenol A hydride diglycidyl ether, hexahydrophthalic acid diglycidyl ether, and a mixture thereof. Examples of the solid resin may include triglycidyl isocyanurate (TGIC). It is preferable to add the solid resin in an amount of about 40-60% based on a total weight of all resins.

Furthermore, the epoxy resin composition may contain acid anhydride or dicarboxylic acid in a 0.5-2.0 molar ratio as a hardening agent based on an equivalence of epoxy, and may further contain a hardening catalyst, such as phosphonium, in a 0.0001-0.1 molar ratio as based on the equivalence of epoxy. Additionally, the epoxy resin composition may contain a heat resistant resin, a light resistant resin and the like in a small amount. The solid resin contained in the epoxy resin composition according to the present invention serves to improve precipitation behaviors of the fluorescent grains dispersed in the resin and to improve dispersion stability of the fluorescent grains.

To provide the epoxy resin composition having improved viscosity, the epoxy resin may contain 50 wt % of solid resin as will be described later, and may be partially hardened before it is mixed with the fluorescent powder. In detail, the epoxy resin composition of the present invention is heated for a short time at a temperature that is lower than a hardening temperature to be partially hardened before it is injected into the light emitting device according to a doping process, thereby increasing the viscosity of the resin to 4000 cps or more, more preferably 7000 cps or more, and to a maximum of 9000 cps. The high viscosity and a high concentration of the solid resin contained in the resin composition contribute to maximal suppression of precipitation of the fluorescent substance having a large grain diameter dispersed in the resin.

Accordingly, the resin composition maintains high dispersion stability even though it is stored for a long time. Needless to say, it is not necessary to harden the liquid resin by heating in order to partially harden the resin composition. It is a matter of course that the liquid resin hardened by use of an additive may be employed instead of use of heat.

According to the present invention, extensive precipitation of the fluorescent substance having a large grain diameter does not occur in the color-converting member, and the fluorescent substance having a large grain diameter is mostly dispersed well in the color-converting member even though partial precipitation occurs around the light emitting diode chip. Hence, the fluorescent substance having a large grain diameter assures high wavelength converting characteristics, and light with the converted wavelength is not blocked by the fluorescent substance having a large grain diameter.

The specification of the present invention does not provide a detailed description of a method of producing the color-converting member, which includes injecting the resin composition into the light emitting device and hardening the resin composition. The detailed description of the method is disclosed in Korean Pat. Application No. 2003-0018028, which is submitted by the applicant of the present invention, and Korean Pat. Laid-Open Publication No. 2002-79953 and the like, and the method is widely known in the art. As for parts that are different from such a typical method, they will be briefly described in example of the present invention.

Having generally described this invention, a further understanding can be obtained by reference to a certain specific example which is provided herein for purposes of illustration only and is not intended to be limiting unless otherwise specified.

Measurement of White Dispersion of a Light Emitting Device, which Depends on an Epoxy Resin Composition

An epoxy resin, acting as a matrix phase, was used as a conventional liquid resin and a liquid/solid resin of the present invention on a light emitting diode chip as shown in Table 1, and fluorescent substances having large and small grain diameters were used as fluorescent powder to form a color-converting member, thereby producing a color-converting light emitting device, and the white dispersion was then measured. The light emitting diode chip included a light emitting layer, which had maximum emission peak at 430 nm and mostly consisted of InGaN. Additionally, the fluorescent substances having small and large grain diameters had mean grain diameters (d₅₀) of 6 μm or less and 20 μm or more, respectively. Furthermore, the fluorescent substance had a garnet structure expressed by A₃B₅O₁₂ and was doped by Ce. In this regard, A included Y, and B included Al.

The liquid/solid resin of the present invention included 50 wt % of TGIC as a solid resin based on a total weight of all resins (excluding the fluorescent substance) and a cyclohexene epoxide derivative as a liquid resin, and a small amount of hardening agent and hardening catalyst were used. Additionally, heat and light resistant resins were used in a small amount as an additive. The prepared resin composition was partially hardened for a short time at a temperature of 80-120° C., which is lower than 150° C. corresponding to a hardening temperature of the resin, mixed with a predetermined amount of fluorescent substance having a large grain diameter, injected into a light emitting diode, and completely hardened at 150° C. for about 1 hour to produce the color-converting member. The amount of the fluorescent substance having a large grain diameter was determined in a trial and error manner so that light, emitted from each light emitting diode employing the resin composition of each sample, had desired chromaticity within a range of a C.I.E chromaticity coordinate system. In Table 1, viscosity of the liquid/solid resin means viscosity of the partially hardened resin composition, and a viscosity change was controlled by changing a partial hardening time. Even though it was possible to produce the liquid/solid resin composition having the viscosity of 9000 cps or more, the production of the liquid/solid resin composition having the viscosity of 9000 cps or more was excluded from the example of the present invention because insufficient workability was assured in a subsequent process in which the resin composition was injected into the light emitting diode.

NT-8XXX series liquid resins, manufactured by Nitto Corp. in Japan, were used as the conventional liquid resin, and they were mixed with the fluorescent substances having small and large grain diameters and completely hardened to produce light emitting devices. Amounts of the fluorescent substances added to the conventional liquid resins were determined in the same manner as the above description.

10,000 white light emitting device samples were produced for every case of Table 1, lights emitted from the light emitting device samples were plotted in the C.I.E. chromaticity coordinate system, and white dispersion was measured. The dispersion means the maximum deviation of x-coordinates of 10,000 samples for combinations of the resin/fluorescent substance in the C.I.E. chromaticity coordinate system.

TABLE 1

| | | Viscosity of the | Grain diameter of | White |
|---|---|---|---|---|
| | Resin | resin (before | the fluorescent | distribution |
| Sample | composition | injection) | substance | (Δx) |
| A | Conventional | 2000-4000 cps | Small diameter | 0.025 |
| | liquid resin | | | |
| B | Conventional | 2000-4000 cps | Large diameter | 0.055 |
| | liquid resin | | | |
| C | Liquid/solid | 3000-4000 cps | Large diameter | 0.032 |
| | resin | | | |
| D | Liquid/solid | 7000-9000 cps | Large diameter | 0.022 |
| | resin | | | |

In Table 1, lesser Δx brings about better white uniformity of the sample. The excellent white uniformity of the sample means that deviations between the samples are low in terms of precipitation of the fluorescent substance and the position of the fluorescent substance in the color-converting member. Accordingly, it can be seen that in the case of the sample D in Table 1, even though the liquid/solid resin having very high viscosity is used, the uniformity does not deteriorate in comparison with the case of using the conventional liquid resin and fluorescent substance having a small grain diameter.

Furthermore, it can be seen that when the samples C and D are compared to each other, higher viscosity of the resin brings about significantly lower white dispersion. This may be explained by the description that an increase in the viscosity of the resin composition contributes to an improvement in dispersion stability of the fluorescent substance, as described above.

Meanwhile, in the case of the sample B employing the conventional liquid resin and the sample D employing the liquid/solid resin of the present invention, viscosities of the resin compositions before the injection are the same as each other and both cases employ the fluorescent substance having a large grain diameter, but there is a large difference in terms of the white dispersion. The difference is considered to be caused by the fact that the resin composition of the sample B does not include the solid resin, and thus, it is presumed that an existence of the solid resin affects the dispersion stability as well as the viscosity.

Measurement of Brightness of a Light Emitting Device, which Depends on a Grain Diameter of a Fluorescent Substance

A solid/liquid epoxy resin having viscosity of 7000-9000 cps was used as a matrix phase and the grain diameter of the fluorescent powder was varied to produce a color-converting light emitting device according to the white dispersion results as described above, and brightness was measured. At this time, a light emitting diode chip and a composition of the fluorescent powder were the same as the above description. Mean grain diameters (d₅₀) of fluorescent powders were 3, 5, 10, 15, 20, 25, 30, 35, and 40 μm, and each fluorescent powder was sieved so that it had a very narrow grain size distribution within ±5% of the mean grain diameter.

TABLE 2

| | Mean grain | | Relative brightness |
|---|---|---|---|
| Sample | diameter (d₅₀, μm) | Brightness (mcd) | (%) |
| D-1 | 3 | 798 | 100.00 |
| D-2 | 5 | 801 | 100.38 |
| D-3 | 10 | 802 | 100.50 |
| D-4 | 15 | 807 | 101.13 |
| D-5 | 20 | 840 | 105.26 |
| D-6 | 25 | 880 | 110.28 |
| D-7 | 30 | 879 | 110.15 |
| D-8 | 35 | 881 | 110.40 |
| D-9 | 40 | 888 | 111.28 |

From Table 2, it can be seen that the higher grain diameter of the powder brings about the higher brightness of the color-converting light emitting device. The reason for this is considered that the powder having a large grain diameter has high color-converting efficiency for excited light. Additionally, as shown in Table 2, when the mean grain diameter of the fluorescent substance was increased to 40 μm, the brightness was continuously increased. Hence, it can be seen that in the case of the color-converting light emitting device produced using an epoxy resin composition of the present invention, a light blocking phenomenon, caused by precipitated fluorescent grains, does not become influential as a critical problem even though the grain diameter of the powder is increased. The reason for this is presumed to be that a precipitation characteristic of the fluorescent substance having a large grain diameter is improved because the epoxy resin composition of the present invention provides excellent dispersion stability. In Table 2, the relative brightness is obtained by expressing a ratio of the brightness of each sample to the brightness of the sample D-1 in a percentage.

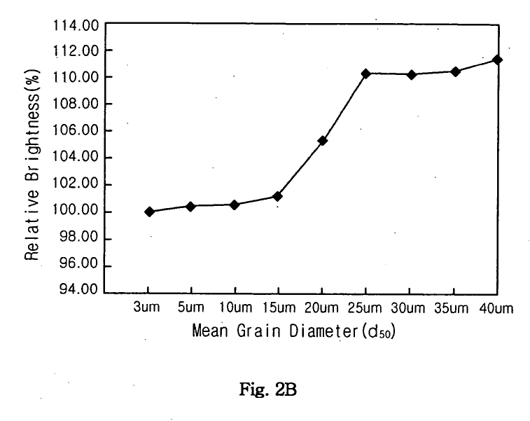

Meanwhile, in FIGS. 2a and 2b, there are illustrated graphs showing the brightness and relative brightness as described in Table 2 as a function of the mean grain diameter for each powder. From the graphs, it can be seen that when the mean grain diameter exceeded 15 μm, the brightness increased sharply with an increase of the grain diameter, and when the mean grain diameter exceeded 25 μm, the brightness increased slightly with an increase of the grain diameter. Accordingly, it is believed that fluorescent powder having a mean grain diameter of 30 μm or more slightly affects an improvement in the brightness.

Through the above description, it can be predicted that the epoxy resin composition of the present invention serves to stabilize dispersion of the fluorescent substance having a large grain diameter, and thus, when it is applied to the color-converting light emitting device in which the fluorescent substance having a large grain diameter is dispersed, the brightness is increased. However, in the epoxy resin composition of the present invention, use of the fluorescent substance having a small grain diameter is not excluded. The reason for this is that since the epoxy resin composition of the present invention provides an improved stable dispersion characteristic for the fluorescent substance having a large grain diameter, when the epoxy resin composition of the present invention employs the fluorescent substance having a small grain diameter, the fluorescent substance having a large grain diameter and fluorescent substance having a small grain diameter are more uniformly dispersed in the color-converting member of the color-converting light emitting device, and advantages of the fluorescent substances are maximally utilized.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

According to the present invention, a transparent resin composition applied onto a light emitting diode chip contains a high amount of solid resin grains and assures very high viscosity due to its partial hardening. Therefore, fluorescent grains contained in the transparent resin composition are stably dispersed during long-term storage.

Furthermore, the transparent resin composition is applied to a color-converting light emitting device employing a fluorescent substance having a large grain diameter, thereby realizing the color-convertirng light emitting device having excellent color distribution. Since the fluorescent substance having a large grain diameter is uniformly distributed in the resin, the color-converting light emitting device according to the present invention has high color-converting efficiency due to the fluorescent substance having a large grain diameter. Moreover, the color-converting light emitting device of the present invention minimizes a light blocking phenomenon, caused by dense precipitation of the fluorescent substance having a large grain diameter, thereby assuring high brightness.

1. A color-converting light emitting device, which includes a gallium nitride-based light emitting diode, and a color-converting member absorbing light from the light emitting diode to convert a wavelength of the light into another wavelength,
wherein the color-converting member comprises a transparent resin and a garnet-based fluorescent powder dispersed in the transparent resin, and the fluorescent powder has a grain size distribution in which a minimum grain diameter is 10 μm or more and a mean grain diameter (d₅₀) is 20 μm or more.

2. A color-converting light emitting device, which includes a gallium nitride-based light emitting diode, and a color-converting member absorbing light from the light emitting diode to convert a wavelength of the light into another wavelength,
wherein the color-converting member comprises a transparent resin and a garnet-based fluorescent powder dispersed in the transparent resin, the transparent resin comprises solid and liquid resins at room temperature, a content of the solid resin is 40-60 wt % based on a weight of the transparent resin, and the fluorescent powder has a grain size distribution in which a mean grain diameter (d₅₀) is 20 μm or more.

3. The color-converting light emitting device as set forth in claim 1 or 2, wherein the garnet-based fluorescent powder is expressed by a compositional formula of A₃B₅O₁₂ and doped by Ce, the A including at least one selected from a group consisting of Y, Lu, Sc, La, Gd, and Sm, the B including at least one selected from a group consisting of Al, Ga, In, and Tb.

4. The color-converting light emitting device as set forth in claim 1 or 2, wherein the grain size distribution of the fluorescent powder forms normal or pseudo-normal distributions.

5. The color-converting light emitting device as set forth in claim 1 or 2, wherein the light emitting diode comprises a light emitting layer made of an InGaN-based compound semiconductor, and has a maximum emission peak within a rang of 430-450 nm.

6. The color-converting light emitting device as set forth in claim 1, wherein the transparent resin comprises a solid resin at room temperature.

7. The color-converting light emitting device as set forth in claim 6, wherein the solid resin includes triglycidyl isocyanurate (TGIC).

8. The color-converting light emitting device as set forth in claim 2, wherein the solid resin includes triglycidyl isocyanurate (TGIC).

9. The color-converting light emitting device as set forth in claim 1 or 2, wherein the mean grain diameter of the fluorescent powder is 50 μm or less.

10. An epoxy resin casting composition for a color-converting light emitting element, comprising:
a transparent resin including solid and liquid resins and having a viscosity of 4000-9000 cps; and
an YAG-based fluorescent powder dispersed in the transparent resin and having a mean grain diameter (d₅₀) of 20 μm or more.

11. The epoxy resin casting composition as set forth in claim 10, wherein the viscosity of the transparent resin is 7000 cps or more.

12. The epoxy resin casting composition as set forth in claim 10, wherein the mean grain diameter of the YAG-based fluorescent powder is 50 μm or less.

13. The epoxy resin casting composition as set forth in claim 10, wherein the transparent resin includes a solid resin consisting of triglycidyl isocyanurate (TGIC).

14. The epoxy resin casting composition as set forth in claim 10, wherein the transparent resin is partially hardened.

15. The epoxy resin casting composition as set forth in claim 8, wherein the transparent resin includes at least one selected from a group consisting of cyclohexene epoxide derivative, bisphenol A hydride diglycidyl ether, and hexahydrophthalic acid glycidyl ether.

16. A method of producing a color-converting light emitting device, comprising:
providing a transparent resin including a solid resin;
partially hardening the transparent resin;
mixing the transparent resin with a garnet-based fluorescent powder having a mean grain diameter of 20 μm or more to provide an epoxy resin composition for the color-converting light emitting device;
applying the transparent resin composition onto a gallium nitride-based semiconductor diode chip; and
completely hardening the resulting transparent resin composition.

17. The method as set forth in claim 16, wherein the partial hardening is conducted through a heat hardening process.
